(19) United States
(12) Patent Application Publication
(10) Pub. No.: US 2014/0020743 A1
(43) Pub. Date: Jan. 23, 2014

(54) SOLAR CELL AND MANUFACTURING METHOD THEREOF

(71) Applicant: TAKUYA KONNO, Kanagawa (JP)

(72) Inventor: TAKUYA KONNO, Kanagawa (JP)

(73) Assignee: E I DU PONT DE NEMOURS AND COMPANY, Wilmington, DE (US)

(21) Appl. No.: 13/555,754

(22) Filed: Jul. 23, 2012

(51) Int. Cl. H01L 31/18; H01L 31/0224

(52) U.S. Cl. 136/256; 438/98; 257/E31.11

(57) ABSTRACT

A method of manufacturing a solar cell comprising steps of: (a) preparing a semiconductor substrate; (b) forming a metal thin film by vapor deposition on the back side of the semiconductor substrate; (c) applying a thick film conductive paste on the front side of the semiconductor substrate; and (d) firing the metal thin film and the applied thick film conductive paste to form a thin film electrode and a thick film electrode respectively.

### FIELD OF THE INVENTION

The present invention relates to a solar cell and its manufacturing method.

### TECHNICAL BACKGROUND OF THE INVENTION

A solar cell having a thick film electrode on the back side in large area warps during firing due to the difference of thermal coefficient of expansion (TCE) between the back side electrode and the substrate.

US20070079868 discloses a solar cell having a front side electrode formed with a silver thick film composition and a back side electrode formed with an aluminum thick film composition comprising amorphous silicon dioxide for warp reduction.

### BRIEF SUMMARY OF THE INVENTION

An objective of the present invention is to reduce warp of a solar cell.

An aspect of the invention relates to a method of manufacturing a solar cell comprising steps of: (a) preparing a semiconductor substrate; (b) forming a metal thin film by vapor deposition on the back side of the semiconductor substrate; (c) applying a thick film conductive paste on the front side of the semiconductor substrate; and (d) firing the metal thin film and the applied thick film conductive paste to form a thin film electrode and a thick film electrode respectively.

Another aspect of the invention relates to a method of a solar cell comprising: (a) a semiconductor substrate; (b) a thin film electrode on the back side of the semiconductor substrate; and (c) a thick film electrode on the front side of the semiconductor substrate.

A solar cell manufactured by the present invention can have less warpage.

### BRIEF DESCRIPTION OF THE DRAWINGS

FIGS. 1A to 1F are drawings for explaining a solar cell manufacturing process.

### DETAILED DESCRIPTION OF THE INVENTION

A method of manufacturing a solar cell having a thin film electrode on the back side and the thick film electrode on the front side is explained below.

The thin film electrode can be defined as the electrode with thickness of 8000 nm or less which is formed by vapor deposition. The thin film electrode contains essentially metal.

The thick film electrode can be defined as the electrode formed by firing a thick film conductive paste. The thick film conductive paste contains at least conductive powder dispersed into an organic medium to form “paste”, having suitable viscosity for applying on a substrate.

The semiconductor substrate of a crystalline silicon solar cell can be a negative type (n-type) silicon substrate comprising an n-type silicon layer and a positive type (p-type) emitter, or p-type silicon substrate comprising a p-type silicon layer and an n-type emitter. The explanation herein uses the p-type silicon substrate.

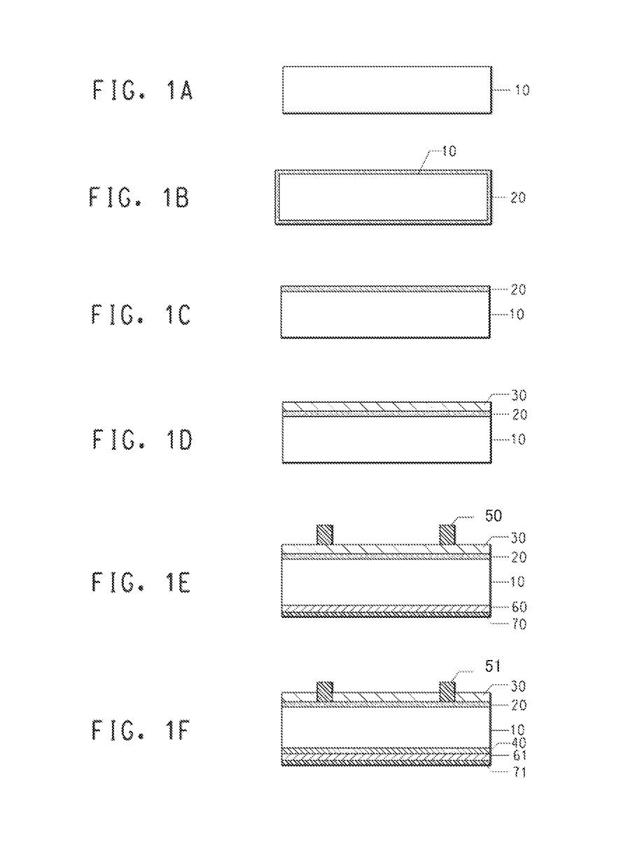

FIG. 1A shows a p-type silicon layer 10. In FIG. 1B, an n-type emitter 20 is formed by the thermal diffusion of phosphorus (P) on the entire surface of the p-type silicon layer 10. After protecting one surface of the n-type emitter 20 with a resist, which does not appear in figures though, the n-type emitter 20 is removed from most surfaces by etching so that the n-type emitter 20 remains only on one main surface as illustrated in FIG. 1C. The resist is then removed with an organic solvent.

An insulating layer 30 can be formed on the front side of the semiconductor substrate which is the n-type emitter 20 as illustrated in FIG. 1D. To form the insulating layer 30, plasma chemical vapor deposition (CVD) can be used. Silicon nitride (SiNₓ), titan oxide (TiO₂), aluminum oxide (Al₂O₃), silicon oxide (SiOₓ), or indium titan oxide (ITO) can be a material for the insulating layer 30. The insulating layer 30 that comes to the front side of the solar cell can be called anti-reflection-coating (ARC). However, the insulating layer 30 is not essential.

In the specification, “front side” is a light-receiving side when the solar cell is actually installed to generate electricity, and “back side” is the opposite side of the front side.

As illustrated in FIG. 1 E, a metal thin film 60 is formed by vapor deposition on the back side of the semiconductor substrate which is the p-type silicon layer 10. The vapor deposition is either physical vapor deposition (PVD) or chemical vapor deposition (CVD) in an embodiment. The vapor deposition is carried out in vacuo in an embodiment.

In PVD, a solid material containing at least one kind of metal is vaporized by thermal energy or plasma energy and then the metal is deposited on the back side of the semiconductor substrate to be a thin film. Sputtering can be available as the PVD. The metal thin film 60 is formed by sputtering in an embodiment. In sputtering, for example direct current high voltage is applied between the semiconductor substrate and a metal as a target in a vacuum chamber in which inert gas such as argon gas is installed. The target of metal is deposited on the substrate by being attacked by the ionized argon.

CVD is an atmosphere controlled process by utilizing thermal energy, photo-energy or radiate energy in a CVD reactor to deposit a material on the back side of the semiconductor substrate to form the thin film 60 as the result of reactions between various gaseous phases and the heated surface of substrates. The CVD can be Plasma-enhanced CVD, Thermal CVD, or Photo-excited CVD.

The metal thin film 60 can comprise a metal selected from the group consisting of silver (Ag), aluminum (Al), nickel (Ni), copper (Cu) and a mixture thereof in an embodiment. The metal thin film 60 can comprise at least Ag or Al, in another embodiment. When the semiconductor substrate is p-type silicon substrate, Al can form back surface field (BSF) which functions as a reducer for recombination by being dispersed into the p-type silicon layer 10.

The metal thin film 60 can be entirely formed on the back side surface of the semiconductor substrate in an embodiment. In another embodiment, the metal thin film 60 can be partially formed at most area of the back side surface of the semiconductor substrate. The metal thin film 60 can be formed on at least 80% of entire area of the back side surface of the semiconductor substrate in an embodiment. The larger area of the thin film electrode on the back side that can be not lighted can increase electrical property of a solar cell.

Optionally a thick film conductive paste 70 to form a tab electrode 71 can be applied on the metal thin film 60. The tab electrode 71 can be formed to electrically interconnect solar cells by soldering a metal wire.

In an embodiment, the thick film conductive paste 70 can be applied on the back side surface of the semiconductor substrate at the open area where the metal thin film 60 is not formed when the metal thin film 60 is partially formed on the backside. In another embodiment, the thick film conductive paste 70 can be applied over the metal thin film 60 when the metal thin film 60 is entirely formed on the backside.

The thick film conductive paste 70 can be partially or entirely overlapped with the metal thin film 60 in an embodiment.

On the front side, a thick film conductive paste 50 can be applied onto the front side of the semiconductor substrate, for example by screen printing, nozzle dispensing or off-set printing. In an embodiment, the thick film conductive paste 50 can be applied onto the insulating layer 30 as illustrated in FIG. 1E.

The thick film conductive paste composition 50 can contain a conductive powder, a glass frit and an organic medium in an embodiment. The thick film conductive composition 50 can comprise 40 to 95 wt % of the conductive powder, 0.5 to 10 wt % of the glass frit and 4 to 59 wt % of the organic medium, based on the total weight of the thick film conductive paste in another embodiment. The conductive powder comprise a metal selected from the group consisting of silver (Ag), aluminum (Al), copper (Cu), nickel (Ni), palladium (Pd), gold (Au), platinum (Pt), and a mixture thereof in an embodiment. The conductive powder comprises Ag and/or Al in another embodiment.

The thick film conductive paste composition 50 on the front side and the thick film conductive paste composition 70 on the back side can be same or different.

For the thick film conductive paste, US patent publication number US20070138659, US20070187652, US20060231802 and US20090001328, can be incorporated herein by reference.

A thin film electrode 61 and a tab electrode 71 on the back side, and a thick film electrode 51 on the front side are obtained by firing the metal thin film 60, the thick film conductive paste 70 on the back side, and the thick film conductive paste 50 on the front side respectively as illustrated in FIG. 1F. On the front side, the thick film conductive paste 50 can fire through the insulating layer 30 during firing so that the thick film electrode 51 can electrically contact with the n-type emitter 20.

The firing can be carried out at the peak setting temperature of 600 to 1000° C. for 1 second to 15 minutes in an embodiment. The firing condition can be 400 to 600° C. for 5 seconds to 23 minutes and over 600° C. for 3 seconds to 19 minutes. Total firing time can be 10 seconds to 30 minutes in an embodiment, 20 seconds to 15 minutes in another embodiment, 30 seconds to 5 minutes in another embodiment. When firing with such conditions, the electrodes can be formed with less damage to the semiconductor layer. The firing time can be counted, for example, from entrance to exit of the furnace.

The thickness of the thin film electrode 61 can be 80 to 5000 nm in an embodiment, 100 to 3000 nm in another embodiment, 125 to 2800 nm in another embodiment, and 200 to 2400 nm in still another embodiment. The semiconductor substrate having the thin film electrode 61 with such thickness can get small warpage. On the other hand, the thick film electrode 51 can be 10 to 70 μm in an embodiment.

In the explanation above, the thick film conductive pastes 50 and 70 on the front and back side, and the metal thin film 60 on the back side are fired at the same time, which is called co-firing. With co-firing, the process can be shorter and simpler to reduce production cost.

Alternatively, the thick film conductive paste 50 and 70 on the front and back side, and the metal thin film 60 on the back side can be fired separately, for example applying and firing the metal thin film 60 on the back side first and then applying and firing the thick film conductive paste 50 and 70 on the front and back side. The firing separately can be available when a suitable firing condition is different for the metal thin film 60 and the thick film conductive paste 50 and 70.

In an embodiment where the process comprises the steps of applying the metal thin film 60 on the back side of the semiconductor substrate, firing the metal thin film 60, applying the thick film conductive paste 50 on the front side of the semiconductor substrate, and firing the thick film conductive paste 50, the firing peak temperature for the metal thin film 60 can be higher than the firing peak temperature for the thick film conductive paste 50. The firing peak temperature for the metal thin film 60 can be 850 to 1000° C. in an embodiment. The firing peak temperature for the thick film conductive paste 50 on the front side can be 600 to 950° C. in an embodiment.

### EXAMPLES

The present invention is illustrated by, but not limited to, the following examples.

A p-type silicon wafer (38 mm×38 mm) having n-type emitter and a silicon nitride layer on the entire front side surface of the n-type emitter was prepared.

Aluminum (Al) was sputtered onto the entire back side surface of the silicon wafer by using a plasma sputtering device (CFS-12P-100, Shibaura Mechatronics Corp.) with installed argon gas to form a back side electrode with thickness of 200 nm, 500 nm or 2000 nm as illustrated in Table 1.

On the front side, a thick film conductive paste containing 84 wt % of silver powder, 5 wt % of the glass frit, 11 wt % of the organic medium was screen-printed in a pattern of one bus bar and finger lines crossing the bus bar.

The printed thick film paste was dried at 150° C. for 5 min.

The Al thin film on the back side and the thick film conductive paste on the front side were co-fired in an IR heating type of a belt furnace (CF-7210, Despatch industry) at the peak temperature setting of 885° C. Firing time from furnace entrance to exit was 78 seconds. The firing condition was 400 to 600° C. for 12 seconds, and over 600° C. for 6 seconds. The belt speed of the furnace was 550 cpm.

For a comparison, a solar cell was made in the same manner of Example 1 except for using a thick film conductive paste on the back side of the silicon wafer as well as the front side. The thick film electrode on the back side contained 70 wt % of aluminum powder, 5 wt % of glass frit and 25 wt % of organic medium.

The warp of the solar cell was measured by the subtraction: “Height of the edge of the solar cell” less “Height of the center of the solar cell”.

The solar cells were tested for light-energy conversion efficiency (Eff, %) with a commercial IV tester (NCT-150AA, NPC Corporation). The Xe Arc lamp in the IV tester simulated the sunlight with a known intensity and spectrum to radiate with air mass value of 1.5 on the front surface of the solar cell. The tester used “four-point probe method” to measure current (I) and voltage (V) at approximately 400 load resistance settings to determine the cell's I-V curve. The bus bar was connected to the multiple probes of the IV tester and electrical signals were transmitted through the probes to the computer for calculating Eff.

As shown in Table 1, the solar cells having the thin film electrode on the back side got smaller warp regardless of the thickness of the thin film electrode (Example 1, 2 and 3) as compared to the solar cell having the thick film electrode on the back side (Com. Example 1). The solar cell largely warped into mound in Com. Example 1 where the center height was 38 μm larger than the edge height.

The Eff. was also higher in the solar cells having the thin film electrode on the back side regardless of the thickness (Example 1, 2 and 3) than the solar cell having the thick film electrode on the back side (Com. Example 1).

TABLE 1

| | | | | Com. |
|---|---|---|---|---|
| Back | Example 1 | Example 2 | Example 3 | Example 1 |
| Back side electrode | 200 nm | 500 nm | 2000 nm | 15 um |
| thickness | | | | |
| Warp (nm) | +14 | +22 | +10 | −38 |
| Eff. (%) | 9.7 | 11.8 | 11.3 | 7.6 |

The Eff. was measured for solar cells in which the thin film electrode on the back side and the thick film electrode on the front side were obtained by firing separately. The thin film electrode on the back side of the silicon wafer was formed by sputtering Al and firing the Al thin film at the setting peak temperature of 960° C. Next, the thick film electrode on the front side of the wafer was formed by screen-printing the thick film conductive paste and firing the thick film conductive paste at 885° C. Besides firing separately at the different setting temperatures, the other materials, processes, conditions and measurements were the same as Examples 1 to 3.

As a result, the Eff was sufficiently high almost regardless of the thickness of the thin film electrode on the back side (Example 4 to 6).

TABLE 2

| | Example 4 | Example 5 | Example 6 |
|---|---|---|---|
| Back side electrode thickness | 200 nm | 500 nm | 2000 nm |
| Eff (%) | 12.9 | 12.1 | 12.1 |

We claim:

1. A method of manufacturing a solar cell comprising steps of:
(a) preparing a semiconductor substrate;
(b) forming a metal thin film by vapor deposition on the back side of the semiconductor substrate;
(c) applying a thick film conductive paste on the front side of the semiconductor substrate; and
(d) firing the metal thin film and the applied thick film conductive paste to form a thin film electrode and a thick film electrode respectively.

2. The method of claim 1, wherein thickness of the thin film electrode is 80 to 5000 nm.

3. The method of claim 1, wherein the metal thin film comprises a metal selected from the group consisting of silver (Ag), aluminum (Al), nickel (Ni), copper (Cu) and a mixture thereof.

4. The method of claim 1, wherein the thick film conductive paste comprises a conductive powder, a glass frit, and an organic medium.

5. The method of claim 1, wherein the metal thin film and the thick film conductive paste are fired separately.

6. The method of claim 5, wherein the deposited metal thin film on the back side is fired, and subsequently the applied thick film conductive paste on the front side is fired.

7. The method of claim 6, wherein firing temperature for the deposited metal thin film on the back side is higher than firing temperature for the applied thick film conductive paste on the front.

8. A solar cell comprising:
(a) a semiconductor substrate;
(b) a thin film electrode on the back side of the semiconductor substrate; and
(c) a thick film electrode on the front side of the semiconductor substrate.

9. The solar cell of claim 8, wherein thickness of the thin film electrode is 80 to 5000 nm.

10. The solar cell of claim 8, wherein the thin film electrode comprises aluminum.
